(19) United States
(12) Patent Application Publication
(10) Pub. No.: US 2013/0126343 A1
(43) Pub. Date: May 23, 2013

(54) SPUTTER TARGET STRUCTURE OF TRANSPARENT CONDUCTIVE LAYER

(71) Applicant: Lin Chen, Shenzhen (CN)

(72) Inventor: Lin Chen, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/379,567

(22) PCT Filed: Nov. 24, 2011
(86) PCT No.: PCT/CN2011/082869

§ 371 Date: Dec. 20, 2011

(30) Foreign Application Priority Data
Nov. 21, 2011 (CN) 201120462142.1

(51) Int. Cl. C23C 14/34

(52) U.S. Cl. 204/298.12

(57) ABSTRACT

The present invention discloses a sputter target structure of a transparent conductive layer, which comprises a middle plate potion, two short-edge thickness-variation end portions, and two long-edge thickness-variation end portions. The thickness of the short-edge thickness-variation end portion is larger than the thickness of the middle plate potion; the thickness of the long-edge thickness-variation end portion is smaller than the thickness of the middle plate potion. Furthermore, the short-edge thickness-variation end portion has an end surface of non-planer shape. The sputter target structure of the transparent conductive layer of the present invention is designed with different thickness variation projects in the different portions according to an actual consumption situation of a sputter target, so that it can decrease a waste of material of the sputter target during operation process, so as to save a cost of the transparent conductive layer.

### FIELD OF THE INVENTION

The present invention relates to a sputter target structure of a transparent conductive layer, and more particularly to a sputter target structure of a transparent conductive layer having thickness variation.

### BACKGROUND OF THE INVENTION

A liquid crystal display (LCD) is a type of flat panel display (FPD) which displays images by the property of the liquid crystal material. In comparison with other display devices, the LCD has the advantages in lightweight, compactness, low driving voltage and low power consumption, and thus has already become the mainstream product in the whole consumer market. In a traditional process of LCD panel, it comprises a front-end array process, a mid-end cell process and a back-end modulation process. The front-end array process is used to produce thin-film transistor (TFT) substrates and color filter (CF) substrates; the mid-end cell process is used to combine the TFT substrate with the CF substrate, then fill liquid crystal into a space therebetween, and cut to form panels with a suitable product size; and the back-end modulation process is used to execute an installation process of the combined panel, a backlight module, a panel driver circuit, an outer frame, etc. The mid-end cell process comprises a producing process of a transparent conductive layer (ITO, indium tin oxide), and the so-called transparent conductive layer (ITO) is a transparent conductive material comprising indium tin oxide.

It is necessary to form the transparent conductive layer on the CF substrate and TFT substrate, and it is generally achieved by using the ITO layer, because the ITO layer has great transparency and conductivity, and further has great etching characterized and reliability, so as to be applied to produce the transparent conductive layer required by the LCD. A traditional producing method of the transparent conductive layer is mainly based on the sputtering principle to sputter an ITO layer onto a substrate by a magnetic controlling method. The sputtering means a physical phenomenon which uses a potential gradient in plasma to accelerate ions (generally using ions of inert gas) for hitting a target (cathode), and make atoms move outward from a surface of the target by transferring the momentum and energy, so as to gain a volatility and fly toward the substrate (anode). The sputter target is a principal consumed material in the producing process of the transparent conductive layer.

Generally, the sputter target has a specific body shape, such as a rectangular cuboid. In the whole producing process of the ITO, used rates of each portions of the sputter target is different. Because the used rates of two ends and edges of the sputter target is lower during operation, the material may be wasted. Besides, the price of the sputter target is quite expensive, so that it directly causes a waste of a cost.

As a result, it is necessary to provide a sputter target structure of a transparent conductive layer to solve the problems existing in the conventional technologies.

### SUMMARY OF THE INVENTION

The main object of the present invention is provides a sputter target structure of a transparent conductive layer to solve the problems existing in the conventional technologies, that is material wasted by an uneven used rate of the sputter target structure.

To achieve the above mentioned object, the present invention provides a sputter target structure of a transparent conductive layer, which comprises a middle plate potion, two short-edge thickness-variation end portions, and two long-edge thickness-variation end portions;

wherein the thickness of the short-edge thickness-variation end portion is larger than the thickness of the middle plate potion; the thickness of the long-edge thickness-variation end portion is smaller than the thickness of the middle plate potion; and the upper surfaces of the middle plate potion, of the two short-edge thickness-variation end portions, and of the two long-edge thickness-variation end portions, are arranged in an identical plane; the short-edge thickness-variation end portion has a chisel-shape end surface.

In one embodiment of the present invention, a width of a cut-edge of the chisel-shape end surface, formed a 45 degrees cut-edge in a right angle edge, is ⅓ to ½ times of the width of the sputter target structure.

In one embodiment of the present invention, a length of the short-edge thickness-variation end portion is 1/16 to ⅛ times of a length of the sputter target structure; and the thickness of the short-edge thickness-variation end portion is 3/2 to 2 times of the thickness of the middle plate potion.

In one embodiment of the present invention, a width of the long-edge thickness-variation end portion is 1/10 to ⅛ times of a width of the sputter target structure; and the thickness of the long-edge thickness-variation end portion is 9/10 to 8/10 times of the thickness of the middle plate potion.

To achieve the above mentioned object, the present invention provides a sputter target structure of a transparent conductive layer, which comprises a middle plate potion, two short-edge thickness-variation end portions, and two long-edge thickness-variation end portions;

wherein the thickness of the short-edge thickness-variation end portion is larger than the thickness of the middle plate potion; the thickness of the long-edge thickness-variation end portion is smaller than the thickness of the middle plate potion; and the upper surfaces of the middle plate potion, of the two short-edge thickness-variation end portions, and of the two long-edge thickness-variation end portions, are arranged in an identical plane; and the short-edge thickness-variation end portion is an end surface of out-protruding double-peak shape.

In one embodiment of the present invention, a length of the short-edge thickness-variation end portion is 1/16 to ⅛ times of a length of the sputter target structure; and the thickness of the short-edge thickness-variation end portion is 3/2 to 2 times of the thickness of the middle plate potion.

In one embodiment of the present invention, a width of the long-edge thickness-variation end portion is 1/10 to ⅛ times of a width of the sputter target structure; and the thickness of the long-edge thickness-variation end portion is 9/10 to 8/10 times of the thickness of the middle plate potion.

To achieve the above mentioned object, the present invention provides a sputter target structure of a transparent conductive layer, which comprises a middle plate potion, two short-edge thickness-variation end portions, and two long-edge thickness-variation end portions;

wherein the thickness of the short-edge thickness-variation end portion is larger than the thickness of the middle plate potion; the thickness of the long-edge thickness-variation end portion is smaller than the thickness of the middle plate potion; and upper surfaces of the middle plate potion, the two short-edge thickness-variation end portions and the two long-edge thickness-variation end portions are arranged in an identical plane.

In one embodiment of the present invention, the short-edge thickness-variation end portion has an end surface of non-planer shape.

In one embodiment of the present invention, the end surface of non-planer shape of end surface is a chisel-shape end surface.

In one embodiment of the present invention, a width of a cut-edge of the chisel-shape end surface, formed a 45 degrees cut-edge in a right angle edge, is ⅓ to ½ times of the width of the sputter target structure.

In one embodiment of the present invention, the short-edge thickness-variation end portion of non-planer shape is an end surface of out-protruding double-peak shape.

In one embodiment of the present invention, a length of the short-edge thickness-variation end portion is 1/16 to ⅛ times of a length of the sputter target structure.

In one embodiment of the present invention, the thickness of the short-edge thickness-variation end portion is 3/2 to 2 times of the thickness of the middle plate potion.

In one embodiment of the present invention, a width of the long-edge thickness-variation end portion is 1/10 to ⅛ times of a width of the sputter target structure.

In one embodiment of the present invention, the thickness of the long-edge thickness-variation end portion is 9/10 to 8/10 times of the thickness of the middle plate potion.

In one embodiment of the present invention, the sputter target structure is disposed on an upper surface of a fixing steel plate, and the shape of the upper surface of the fixing steel plate is corresponding to a shape of a bottom of the sputter target structure.

The sputter target structure of the transparent conductive layer of the present invention is designed with different variation projects in the different portions according to an actual consumption situation of a sputter target, so that it can decrease a waste of material of the sputter target during operation process, so as to save a cost of the transparent conductive layer.

### DESCRIPTION OF THE DRAWINGS

FIG. 1 is a schematic view disclosing a material consumption of a sputter target of a transparent conductive layer according to the present invention;

FIG. 2 is a perspective schematic view of the sputter target of the transparent conductive layer according to a first preferred embodiment of the present invention;

FIG. 3A is a perspective schematic view of the sputter target of the transparent conductive layer according to a second preferred embodiment of the present invention;

FIG. 3B is a perspective schematic view of another view angle of FIG. 3A;

FIG. 4 is a perspective schematic view of the sputter target of the transparent conductive layer according to a third preferred embodiment of the present invention; and

FIG. 5 is a perspective schematic view of the sputter target of the transparent conductive layer according to a fourth preferred embodiment of the present invention.

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

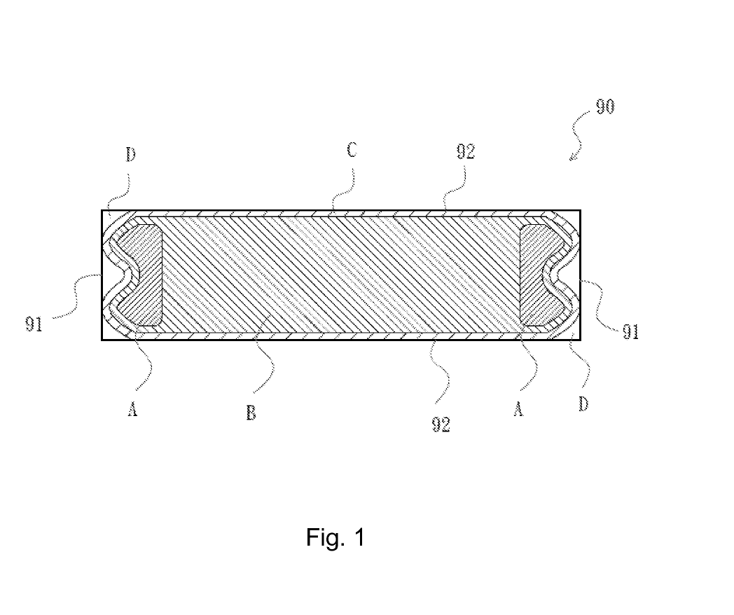

Referring now to FIG. 1, a schematic view disclosing a material consumption of a sputter target of a transparent conductive layer according to the present invention is illustrated in FIG. 1. As shown in FIG. 1, the sputter target 90 is a principal consuming material in a producing process of the transparent conductive layer, which comprises two short-edges 91 and two long-edges 92. FIG. 1 is showing a consuming situation of the sputter target 90 with a curved graph of material thickness variation, wherein the order of the consuming material is that: the most is in area A, the next is area B, then area C, and area D is no consuming material. Hence, it is known from FIG. 1, in the producing process of the transparent conductive layer, generally, the consumption of the sputter target 90 close to the two short-edges 91 are greater than that in middle; and the consumption of the sputter target 90 close to the two long-edges 92 are less than that in middle. It is necessary to be noticed, thought the consumption of the sputter target 90 close to the two short edges are greater than that in middle, it presents an irregular consumption distribution in the potions, and the consumption situation appears an out-protruding double-peak shape.

According to the actual consumption situation of a sputter target of a transparent conductive layer in the background technologies, the present invention provides below preferred embodiments of thickness variation of the sputter target to decrease a waste of material of the sputter target during operation process, so as to save a cost of the transparent conductive layer.

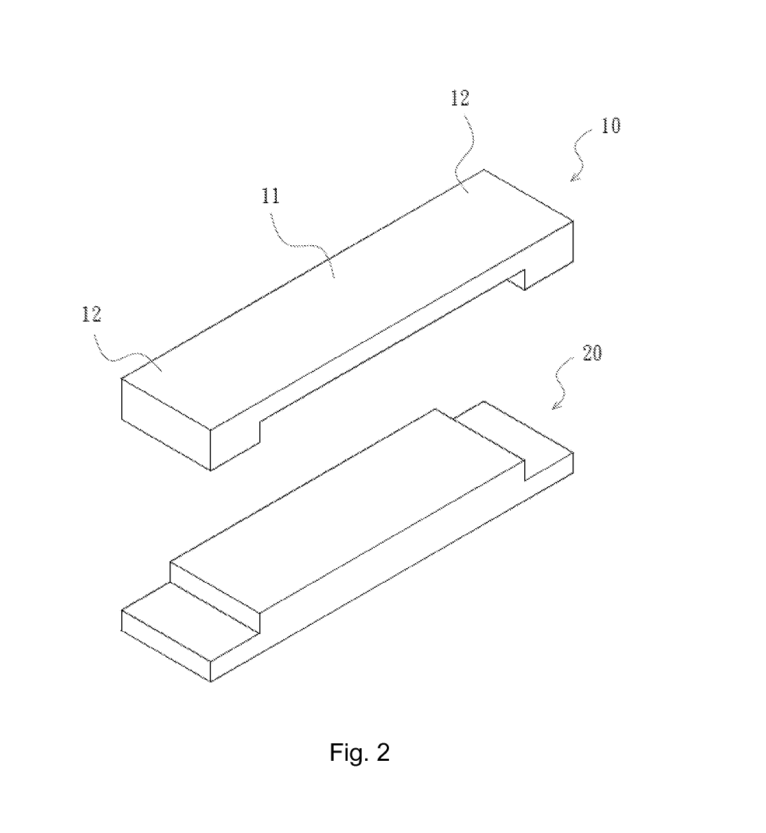

Referring now to FIG. 2, a perspective schematic view of the sputter target of the transparent conductive layer according to a first preferred embodiment of the present invention is illustrated in FIG. 2. A sputter target structure 10 according to a first preferred embodiment has a shape of a rectangular sheet body. For a convenient of description, two shorter edges of the sputter target structure 10 are called short-edges, and two longer edges of the sputter target structure 10 are called long-edges. As shown in FIG. 2, the sputter target structure 10 comprises a middle plate potion 11 and two short-edge thickness-variation end portions 12. Besides, the upper surfaces of the middle plate potion 11 and of the two short-edge thickness-variation end portions 12 are arranged in an identical plane.

As shown in FIG. 2, in this preferred embodiment, because a consumption of the short-edge thickness-variation end portion 12 of the sputter target structure 10 is more than the middle plate potion 11, the short-edge thickness-variation end portions 12 are designed thicker, and the middle plate potion 11 is designed thinner. It can decrease a material waste of the middle plate potion 11 by the design of the short-edge thickness-variation end portions 12. Furthermore, as shown in FIG. 2, the sputter target structure 10 is disposed on an upper surface of a fixing steel plate 20, and the shape of the upper surface of the fixing steel plate 20 is corresponding to the shape of the bottom of the sputter target structure 10.

Preferably, the length of the short-edge thickness-variation end portion 12 is one sixteenth ( 1/16) to one eighth (⅛) times of the length of the sputter target structure 10; the thickness of the short-edge thickness-variation end portion 12 is three half ( 3/2) to two (2) times of the thickness of the middle plate potion 11.

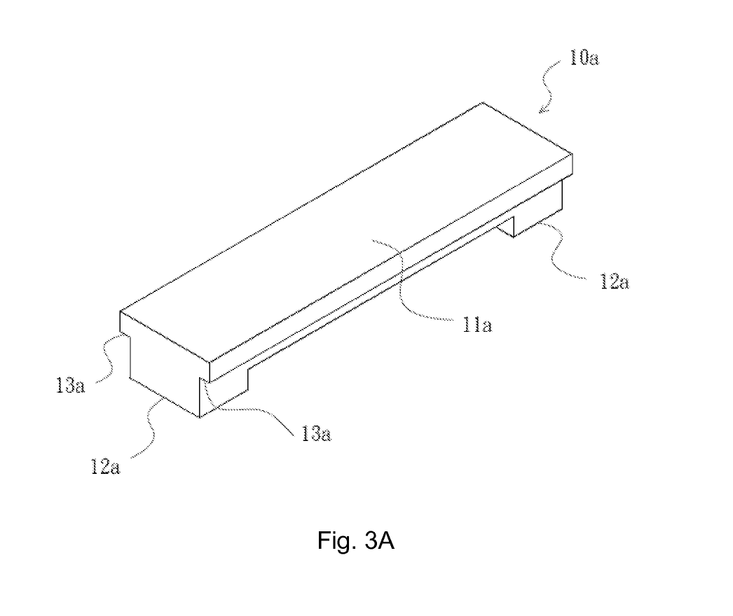

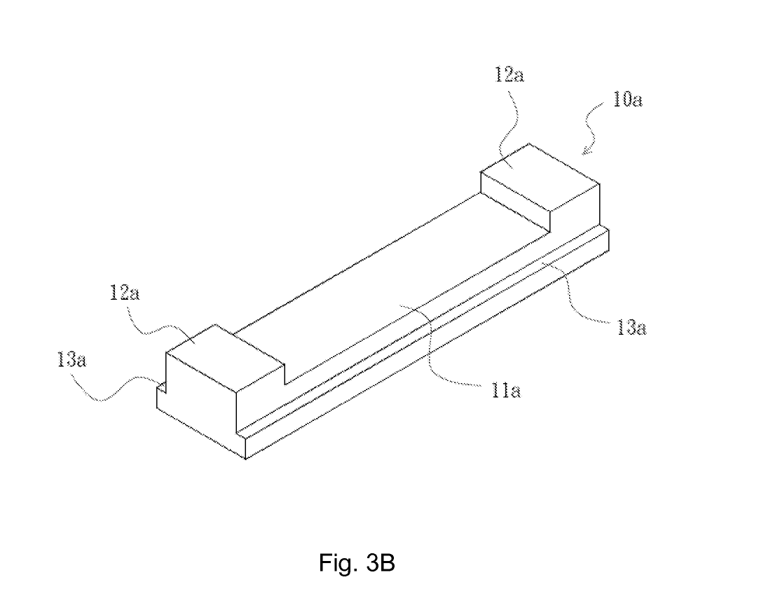

Referring now to FIGS. 3A and 3B, a perspective schematic view of the sputter target of the transparent conductive layer according to a second preferred embodiment of the present invention is illustrated in FIG. 3A, and a perspective schematic view of another view angle of FIG. 3A is illustrated in FIG. 3B. The difference between a sputter target structure 10a according to the second preferred embodiment of the present invention and the sputter target structure 10 according to the first preferred embodiment of the present invention is that: in this preferred embodiment, the sputter target structure 10a is further provided with two the long-edge thickness-variation end portions 13a in two edges of a width direction (shorter direction) of the sputter target structure 10a. Besides, the upper surfaces of the middle plate potion 11a and of the two long-edge thickness-variation end portions 13a are arranged in an identical plane.

Because a consumption of the long-edge thickness-variation end portion 13a of the sputter target structure 10a is more than the middle plate potion 11a, the long-edge thickness-variation end portions 13a are designed thinner than the middle plate potion 11a. It can decrease a material waste of the sputter target structure 10a in the long-edge thickness-variation end portions 13a by the design of the long-edge thickness-variation end portions 13a.

Preferably, the width of the long-edge thickness-variation end portion 13a is one tenth ( 1/10) to one eighth (⅛) times of the width of the sputter target structure 10a; the thickness of the long-edge thickness-variation end portion 13a is nine tenth ( 9/10) to eight tenth ( 8/10) times of the thickness of the middle plate potion 11a.

In this preferred embodiment, the sputter target structure of the transparent conductive layer comprises a middle plate potion, two short-edge thickness-variation end portions, and two long-edge thickness-variation end portions. Among them, the thickness of the short-edge thickness-variation end portion is larger than the thickness of the middle plate potion; the thickness of the long-edge thickness-variation end portion is smaller than the thickness of the middle plate potion; and the upper surfaces of the middle plate potion, of the two short-edge thickness-variation end portions, and of the two long-edge thickness-variation end portions, are arranged in an identical plane.

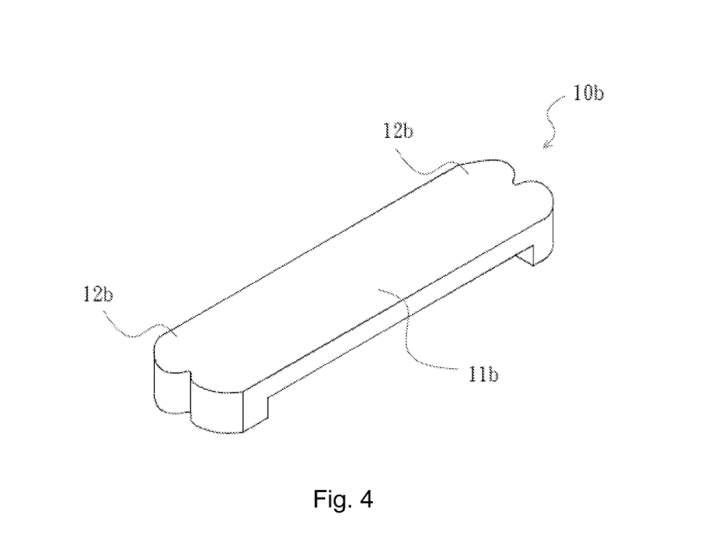

Referring now to FIG. 4, a perspective schematic view of the sputter target of the transparent conductive layer according to a third preferred embodiment of the present invention is illustrated in FIG. 4. The difference between a sputter target structure 10b according to the third preferred embodiment of the present invention and the sputter target structure 10 according to the first preferred embodiment of the present invention is that: in this preferred embodiment, the short-edge thickness-variation end portion 12b has an end surface of non-planer shape. The so-called shape end of non-planer surface which means perpendicular surfaces on an outside of the short-edge thickness-variation end portion 12b have a non-single plane. Specifically, the non-planer shape of the short-edge end surface is an out-protruding double-peak shape. Because the consumption close to the two short-edges of the sputter target construct 10b are greater than that in middle, and it presents an irregular distribution in that potions that material consumption situation appears an out-protruding double-peak shape, and no consumption in the area out of the double-peak shape. Hence, the short-edge thickness-variation end portion 12b is designed as a shape corresponding to the shape having no material consumption, so as to decrease an unnecessary material waste in the two ends of the sputter target structure 10b

Furthermore, the third preferred embodiment of the present invention and the second preferred embodiment also can combine another possible embodiment (not shown).

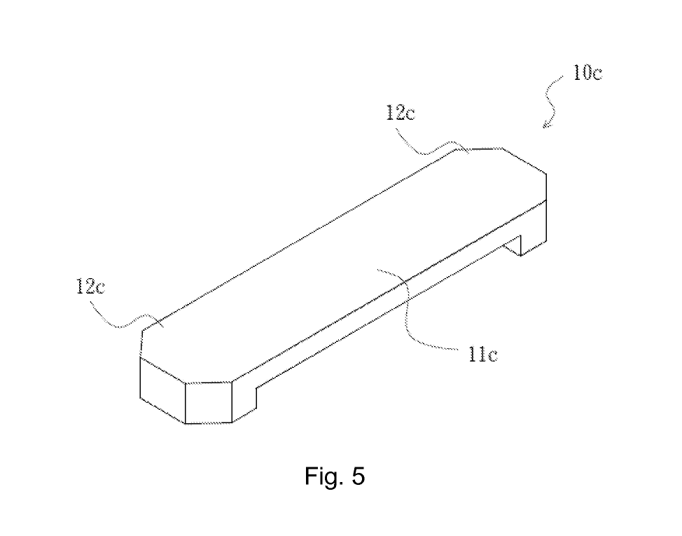

Referring now to FIG. 5, a perspective schematic view of the sputter target of the transparent conductive layer according to a fourth preferred embodiment of the present invention is illustrated in FIG. 5. The difference between a sputter target structure 10c according to the fourth preferred embodiment of the present invention and the sputter target structure 10 according to the first preferred embodiment of the present invention is that: in this preferred embodiment, the non-planer shape of end surface of the short-edge thickness-variation end portion 12c is a chisel-shape end surface, it means the two corners have a design of chamfer. In here, the so-called chamfer is a chamfer in a field of a mechanical processing, or called beveling, and generally is formed a cut-edge of 45 degrees in a right angle. Although the consumption close to the two short edges of the sputter target construct 10c presents a consumption situation of an out-protruding double-peak shape, when consider that it is possible to increase a cost in the third preferred embodiment as shown in FIG. 4, so that the present invention uses another simpler shape of the end surface to achieve a similar effect for saving material.

Preferably, the chamfer width of the chisel-shape end surface 12c is one third (⅓) to one half (½) times of the width of the sputter target structure 10c.

Furthermore, the third preferred embodiment of the present invention and the second preferred embodiment also can combine another possible embodiment (not shown).

As above mentioned, in comparison with the conventional technologies, because a general sputter target does not specially design in the shape thereof, and a used rates of each portions of the sputter target is different in the whole producing process of the ITO, so that the used rates of two ends and edges of the sputter target is lower during operation, so as to waste the material. Besides, the price of the sputter target is quite expensive, so it directly causes a waste of a cost. The sputter target structure 10 of the transparent conductive layer of the present invention is designed with different variation projects in the different portions according to an actual consumption situation of a sputter target 10, so that it can decrease a waste of material of the sputter target during operation process, so as to save a cost of the transparent conductive layer.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A sputter target structure of a transparent conductive layer, characterized in that: the sputter target structure comprises a middle plate potion, two short-edge thickness-variation end portions, and two long-edge thickness-variation end portions;
wherein the thickness of the short-edge thickness-variation end portion is larger than the thickness of the middle plate potion;
the thickness of the long-edge thickness-variation end portion is smaller than the thickness of the middle plate potion; and
upper surfaces of the middle plate potion, the two short-edge thickness-variation end portions and the two long-edge thickness-variation end portions, are arranged in an identical plane;
and the short-edge thickness-variation end portion has a chisel-shape end surface.

2. The sputter target structure of the transparent conductive layer according to claim 1, characterized in that: a width of a cut-edge of the chisel-shape end surface, formed a 45 degree cut-edge in a right angle edge, is ⅓ to ½ times of the width of the sputter target structure.

3. The sputter target structure of the transparent conductive layer according to claim 1, characterized in that: a length of the short-edge thickness-variation end portion is 1/16 to ⅛ times of a length of the sputter target structure; and the thickness of the short-edge thickness-variation end portion is 3/2 to 2 times of the thickness of the middle plate potion.

4. The sputter target structure of the transparent conductive layer according to claim 1, characterized in that: a width of the long-edge thickness-variation end portion is 1/10 to ⅛ times of a width of the sputter target structure; and the thickness of the long-edge thickness-variation end portion is 9/10 to 8/10 times of the thickness of the middle plate potion.

5. A sputter target structure of a transparent conductive layer, characterized in that: the sputter target structure comprises a middle plate potion, two short-edge thickness-variation end portions, and two long-edge thickness-variation end portions;
wherein the thickness of the short-edge thickness-variation end portion is larger than the thickness of the middle plate potion;
the thickness of the long-edge thickness-variation end portion is smaller than the thickness of the middle plate potion;
upper surfaces of the middle plate potion, the two short-edge thickness-variation end portions and the two long-edge thickness-variation end portions are arranged in an identical plane; and
the short-edge thickness-variation end portion is an end surface of out-protruding double-peak shape.

6. The sputter target structure of the transparent conductive layer according to claim 5, characterized in that: a length of the short-edge thickness-variation end portion is 1/16 to ⅛ times of a length of the sputter target structure; and the thickness of the short-edge thickness-variation end portion is 3/2 to 2 times of the thickness of the middle plate potion.

7. The sputter target structure of the transparent conductive layer according to claim 5, characterized in that: a width of the long-edge thickness-variation end portion is 1/10 to ⅛ times of a width of the sputter target structure; and the thickness of the long-edge thickness-variation end portion is 9/10 to 8/10 times of the thickness of the middle plate potion.

8. A sputter target structure of a transparent conductive layer, characterized in that: the sputter target structure comprises a middle plate potion, two short-edge thickness-variation end portions, and two long-edge thickness-variation end portions;
wherein the thickness of the short-edge thickness-variation end portion is larger than the thickness of the middle plate potion;
the thickness of the long-edge thickness-variation end portion is smaller than the thickness of the middle plate potion; and upper surfaces of the middle plate potion, the two short-edge thickness-variation end portions and the two long-edge thickness-variation end portions are arranged in an identical plane.

9. The sputter target structure of the transparent conductive layer according to claim 8, characterized in that: the short-edge thickness-variation end portion has an end surface of non-planer shape.

10. The sputter target structure of the transparent conductive layer according to claim 9, characterized in that: the end surface of non-planer shape is a chisel-shape end surface.

11. The sputter target structure of the transparent conductive layer according to claim 10, characterized in that: a width of a cut-edge of the chisel-shape end surface, formed a 45 degrees cut-edge in a right angle edge, is ⅓ to ½ times of the width of the sputter target structure.

12. The sputter target structure of the transparent conductive layer according to claim 9, characterized in that: the short-edge thickness-variation end portion of non-planer shape is an end surface of out-protruding double-peak shape.

13. The sputter target structure of the transparent conductive layer according to claim 8, characterized in that: a length of the short-edge thickness-variation end portion is 1/16 to ⅛ times of a length of the sputter target structure.

14. The sputter target structure of the transparent conductive layer according to claim 8, characterized in that: the thickness of the short-edge thickness-variation end portion is 3/2 to 2 times of the thickness of the middle plate potion.

15. The sputter target structure of the transparent conductive layer according to claim 8, characterized in that: a width of the long-edge thickness-variation end portion is 1/10 to ⅛ times of a width of the sputter target structure.

16. The sputter target structure of the transparent conductive layer according to claim 8, characterized in that: the thickness of the long-edge thickness-variation end portion is 9/10 to 8/10 times of the thickness of the middle plate potion.

17. The sputter target structure of the transparent conductive layer according to claim 8, characterized in that: the sputter target structure is disposed on an upper surface of a fixing steel plate, and the shape of the upper surface of the fixing steel plate is corresponding to a shape of a bottom of the sputter target structure.
